(19) United States
(12) Patent Application Publication
(10) Pub. No.: US 2022/0107749 A1
(43) Pub. Date: Apr. 7, 2022

(54) CELL SIZE-BASED MEMORY DIAGNOSTIC

(71) Applicant: LENOVO (Singapore) PTE. LTD., New Tech Park (SG)

(72) Inventors: Davy Souza, Sorocaba (BR); Fernanda Watanabe, Sorocaba (BR); Rafael Machado, Sorocaba (BR); Marcelo Ferreira, Campina (BR)

(21) Appl. No.: 17/063,625

(22) Filed: Oct. 5, 2020

(51) Int. Cl. G06F 3/06

(52) U.S. Cl. CPC G06F 3/0653; G06F 3/0655; G06F 3/0676; G06F 3/0679; G06F 3/0614

(57) ABSTRACT

For cell size-based memory diagnostics, a processor selects a test mask based on a number of bits per memory cell in a memory. The test mask stresses cell boundaries. The processor writes the test mask to a plurality of memory cells. The processor determines interference at a first memory cell.

### FIELD

The subject matter disclosed herein relates to memory diagnostics and more particularly relates to cell size-based memory diagnostics.

### BACKGROUND

Memory diagnostics are performed on memories to validate all memory elements.

### BRIEF SUMMARY

An apparatus for cell size-based memory diagnostics is disclosed. The apparatus includes a processor and a memory storing code executable by the processor. The processor selects a test mask based on a number of bits per memory cell in a memory. The test mask stresses cell boundaries. The processor writes the test mask to a plurality of memory cells. The processor determines interference at a first memory cell. A method and program product also perform the functions of the apparatus.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1A is a schematic block diagram illustrating one embodiment of a memory;

FIG. 1B is a schematic block diagram illustrating one embodiment of a memory address;

FIG. 2 is a schematic diagram illustrating one alternate embodiment of a memory;

FIG. 3 is a schematic block diagram illustrating one embodiment of a diagnostic data;

FIG. 4 is a schematic block diagram illustrating one embodiment of a computer;

FIG. 5 is a schematic flow chart diagram illustrating one embodiment of a memory test method; and

FIG. 6 is a schematic flow chart diagram illustrating one embodiment of a three-dimensional memory test method.

### DETAILED DESCRIPTION

As will be appreciated by one skilled in the art, aspects of the embodiments may be embodied as a system, method, or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices may be tangible, non-transitory, and/or non-transmission. The storage devices may not embody signals. In a certain embodiment, the storage devices only employ signals for accessing code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in code and/or software for execution by various types of processors. An identified module of code may, for instance, comprise one or more physical or logical blocks of executable code which may, for instance, be organized as an object, procedure, or function. Nevertheless, the executables of an identified module need not be physically located together but may comprise disparate instructions stored in different locations which, when joined logically together, comprise the module and achieve the stated purpose for the module.

Indeed, a module of code may be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different computer readable storage devices. Where a module or portions of a module are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing.

More specific examples (a non-exhaustive list) of the storage device would include the following: an electrical connection having one or more wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

Code for carrying out operations for embodiments may be written in any combination of one or more programming languages including an object oriented programming language such as Python, Ruby, R, Java, Java Script, Smalltalk, C++, C sharp, Lisp, Clojure, PHP, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The embodiments may transmit data between electronic devices. The embodiments may further convert the data from a first format to a second format, including converting the data from a non-standard format to a standard format and/or converting the data from the standard format to a non-standard format. The embodiments may modify, update, and/or process the data. The embodiments may store the received, converted, modified, updated, and/or processed data. The embodiments may provide remote access to the data including the updated data. The embodiments may make the data and/or updated data available in real time. The embodiments may generate and transmit a message based on the data and/or updated data in real time. The embodiments may securely communicate encrypted data. The embodiments may organize data for efficient validation. In addition, the embodiments may validate the data in response to an action and/or a lack of an action.

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise. The term “and/or” indicates embodiments of one or more of the listed elements, with “A and/or B” indicating embodiments of element A alone, element B alone, or elements A and B taken together.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. This code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods, and program products according to various embodiments. In this regard, each block in the schematic flowchart diagrams and/or schematic block diagrams may represent a module, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

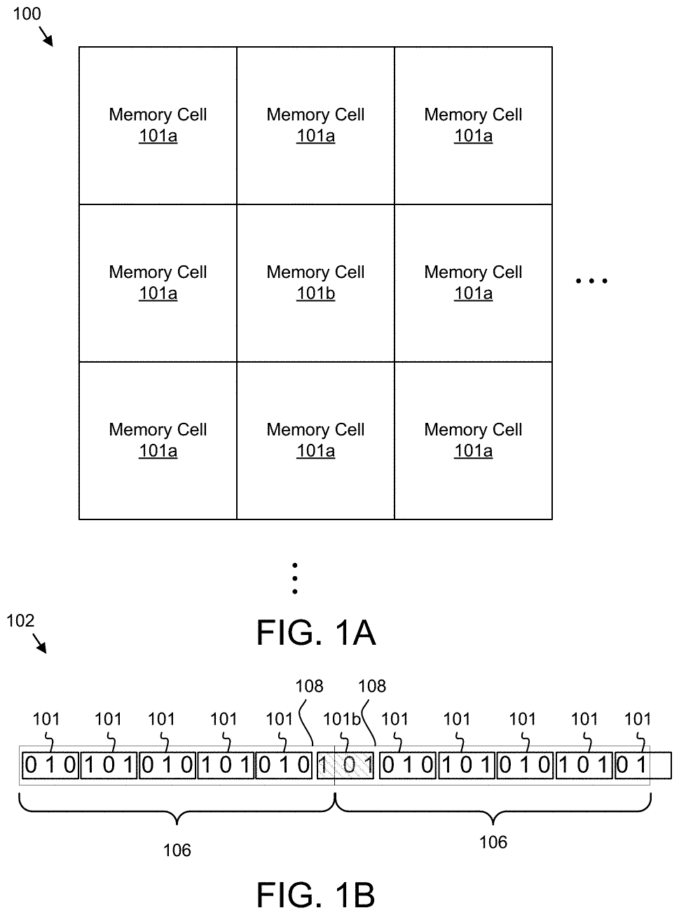

FIG. 1A is a schematic block diagram illustrating one embodiment of a memory 100. The memory 100 may be embodied in a semiconductor device. In the depicted embodiment, the memory 100 includes a plurality of memory cells 101. Each memory cell 101 may store one or more bits of data. For example, a memory cell 101 may store one, two, three, four, five, or more bits of data. A given memory cell 101b may have one or more neighbor memory cells 101a.

A typical memory 100 is often tested with one or more diagnostics to validate that each bit of the memory 100 is functioning properly. Unfortunately, memory diagnostic algorithms do not consider how many bits the memory cell 101 includes. As a result, some bits may be unchecked and/or inadequately checked during diagnostics. The embodiments described herein select a test mask based on the number of bits per memory cell 101 in the memory 100 as will be described hereafter. The test mask may stress cell boundaries. As a result, diagnostics performed on the memory 100 more thoroughly validate the proper functioning of the memory 100. Thus, memory diagnostics that are performed during manufacturing and/or memory test will identify more defective memories 100.

FIG. 1B is a schematic block diagram illustrating one embodiment of a memory address 102 for the memory 100. Data bits are stored in a plurality of memory cells 101. In the depicted embodiment, each memory cell 101 stores three bits. A cell boundary 108 may separate bits from one memory cell 101 and bits from another memory cell 101.

A given memory cell 101b may store bits for two data segments 106. As a result, some bits in the given memory cell 101b may be unchecked and/or inadequately checked during diagnostics.

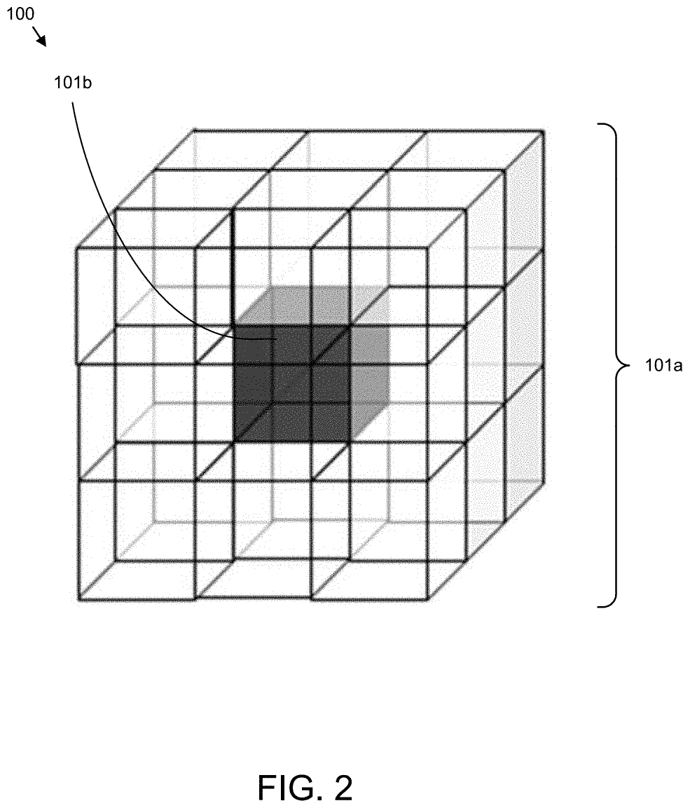

FIG. 2 is a schematic diagram illustrating one alternate embodiment of a memory 100. In the depicted embodiment, the memory 100 is a three-dimensional (3D) memory 100. A given memory cell 101b is shown with the plurality of neighbor memory cells 101a. In the past, memory diagnostics have not considered the effects of neighbor memory cells 101a on a given memory cell 101b. The embodiments described herein also determine interference from neighbor memory cells 101a in a three-dimensional memory 100.

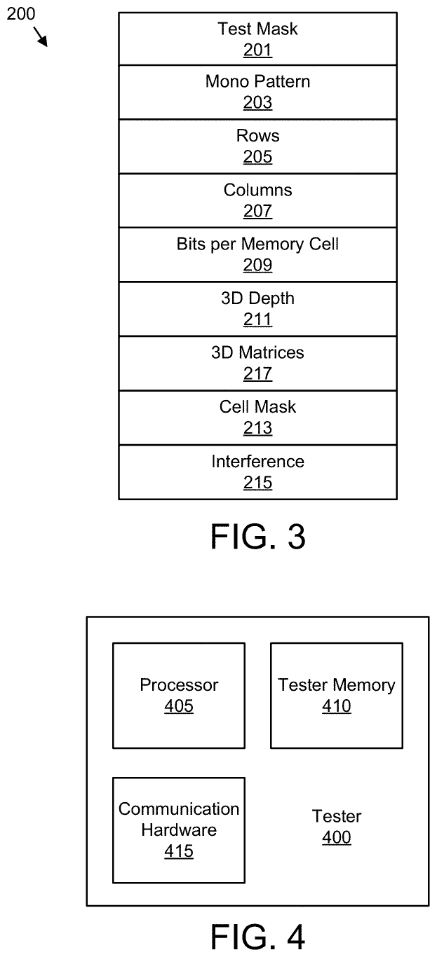

FIG. 3 is a schematic block diagram illustrating one embodiment of a diagnostic data 200. The diagnostic data 200 may be used to determine interference between memory cells 101. The diagnostic data 200 may be organized as a data structure in a computer memory. In the depicted embodiment, the diagnostic data 200 includes a test mask 201, a mono pattern 203, rows 205, columns 207, bits per memory cell 209, a 3D depth 211, 3D matrices 217, a cell mask 213, and interference 215.

The test mask 201 may be written to a plurality of memory cells 101. In one embodiment, the test mask 201 is written to a memory address 102. In addition, the test mask 201 may be formatted to be written to one or more data segments 106.

The mono pattern 203 may be written to specified memory cells 101. The mono pattern 203 may comprise all zeros. Alternatively, the mono pattern 203 may include all ones. The rows 205 may specify a number of memory rows. The columns 207 may specify a number of memory columns.

The bits per memory cell 209 may specify a number of bits in each memory cell 101. The bits per memory cell 209 may be derived from a memory type. For example, the bits per memory cell 209 for a single-level cell (SLC) memory 100 may be one bit. The bits per memory cell 209 for a multi-level cell (MLC) memory 100 may be two bits. The bits per memory cell 209 for a triple-level cell (TLC) memory 100 may be three bits. The bits per memory cell 209 for a quad level cell (QLC) memory 100 may be four bits. The bits per memory cell 209 for a penta-level cell (PLC) memory 100 may be five bits. In one embodiment, the test mask 201 is selected based on the bits per memory cell 209.

The 3D depth 211 may specify a depth of memory cells 101 in a 3D memory 100. The 3D matrices 217 may specify a number of matrices of memory cells 101 in the 3D memory 100.

The cell mask 213 may be written to specified memory cells 101 such as neighbor memory cells 101a. The cell mask 213 may include all ones. Alternatively, the cell mask 213 may include all zeros. In one embodiment, the cell mask 213 is the opposite pattern from the mono pattern 203.

The interference 215 may record errors, anomalies, and the like at one or more bits of the memory cell 101. In one embodiment, the interference 215 is determined from a value error. For example, if the value of one was expected and a value of zero was read resulting in a value error, the interference 215 determined from the value error.

In one embodiment, the interference 215 may be determined from a voltage level outside of an acceptable range. For example, a test system may measure the voltage of a bit in the memory cell 101 and determine an error if the voltage level is outside of the acceptable range.

FIG. 4 is a schematic block diagram illustrating one embodiment of a tester 400. The tester 400 may be a semiconductor test system. In addition, the tester 400 may embedded in a memory controller for the memory 100. The tester 400 may perform diagnostics on the memory 100. In the depicted embodiment, the tester 400 includes a processor 405, a tester memory 410, and communication hardware 415. The tester memory 410 may be separate and distinct from the memory 100. The tester memory 410 may store code and data. The processor 405 may execute the code and process the data. The communication hardware 415 may communicate with other devices such as the memory 100.

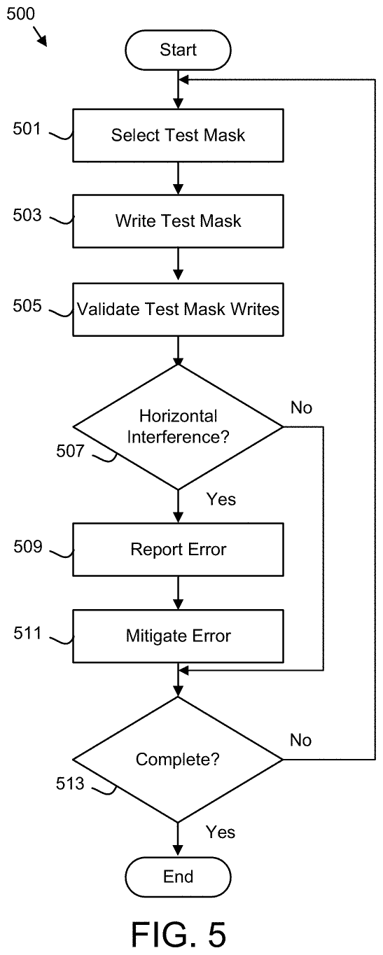

FIG. 5 is a schematic flow chart diagram illustrating one embodiment of a memory test method 500. The method 500 may test a memory 100 for interference 215. In one embodiment, the method 500 tests a two-dimensional memory 100 such as is shown in FIG. 1A. the method 500 may be performed by the processor 405.

The method 500 starts, and in one embodiment, the processor 405 selects 501 the test mask 201 based on the bits per memory cell 209 in the memory 100. The test mask 201 may be selected 501 to stress the cell boundaries 108.

In one embodiment, the test mask is selected 501 from Table 1 based on the bits per memory cell 209.

TABLE 1

| Bits per Memory | |
|---|---|
| Cell 209 | Test Mask 201 (Hex) |
| 1 | 0x5555555555555555 |
| 2 | 0xAAAAAAAAAAAAAAAA |
| 3 | 0x4924924924924924 |
| 3 | 0x2492492492492492 |
| 3 | 0x9249249249249249 |
| 4 | 0x8888888888888888 |
| 5 | 0x0842108421084210 |
| 5 | 0x1084210842108421 |
| 5 | 0x2108421084210842 |
| 5 | 0x4210842108421084 |
| 5 | 0x8421084210842108 |

In a certain embodiment, where a plurality of test masks 201 are available for a given bits per memory cell 209, one test mask 201 of the plurality of test masks 201 may be selected 501 at random.

The processor 405 further writes 503 the test mask 201 to the plurality of memory cells 101 in the memory 100. The test mask 201 may be written to a plurality of memory addresses 102. In addition, the test mask 201 may be written to a plurality of data segments 106.

The processor 405 may validate 505 the writes of the test mask 201. In one embodiment, the processor 405 reads values from the memory cells 101, the memory addresses 102, and/or the data segments 106 and compares the values to the test mask 201. The writes are validated if the values match the test mask 201.

The processor 405 may determine 507 interference 215 at a first memory cell 101. In one embodiment, the interference 215 is determined 507 from a value error. In addition, the interference 215 may be determined from a voltage level outside of an acceptable range.

If interference 215 is determined 507, the processor 405 reports 509 the interference 215 as an error. In one embodiment, the processor 405 mitigates 511 the error. For example, the processor 405 may direct a memory address 102 to a replacement memory cell 111, replacement memory address 102, and/or replacement data segment 106.

If no interference 215 is determined 507 or in response to reporting 509 the error and/or mitigating 511 the error, the processor 405 determines 513 if all memory cells 101, memory addresses 102, and/or data segments 106 have been tested and/or if the diagnostic is complete. If all memory cells 101, memory addresses 102, and/or data segments 106 have not been tested and/or if the diagnostic is not complete, the processor 405 may loop to select 501 the test mask 201. In a certain embodiment, a first test mask 201 is reselected for each iteration. Alternatively, a new test mask 201 may be selected each iteration. If the diagnostic is complete, the method 500 ends.

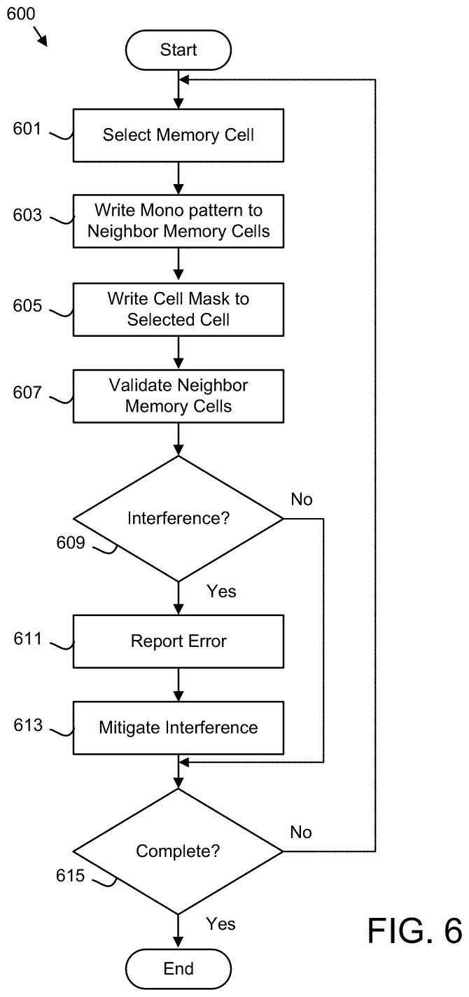

FIG. 6 is a schematic flow chart diagram illustrating one embodiment of a 3D memory test method 600. The method 600 may test a 3D memory 100 such as is shown in FIG. 2. The method 600 may be performed by the processor 405.

The method 600 starts, and in one embodiment, the processor 405 selects 601 a given memory cell 101b of a plurality of memory cells 101. The given memory cell 101b may be selected sequentially. Alternatively, the given memory cells 101b may be selected randomly.

The processor 405 further writes 603 the mono pattern 203 to neighbor memory cells 101a of the selected given memory cell 101b. The mono pattern 203 may be written 603 to all neighbor memory cells 101a of the selected given memory cell 101b.

The processor 405 writes 605 the cell mask 213 to the selected given memory cell 101b. The mono pattern 203 may be zeros and the cell mask 213 may be ones. Alternatively, the mono pattern 203 may be ones and the cell mask 213 may be zeros. The processor 405 may validate 607 the neighbor memory cells 101a. In one embodiment, the processor 405 reads values from the neighbor memory cells 101a and compares the values to the mono pattern 203. The writes are validated if the values match the mono pattern 203. The processor 405 may also measure a voltage value for bits of the neighbor memory cells 101a. The writes may be validated if measured voltages are withing an acceptable range.

The processor 405 may determine 609 interference 215 at a first neighbor memory cell 101a. The interference 215 may be determine 609 from a value error. In addition, the interference 215 may be determine 609 from a voltage level outside of the acceptable range.

If interference 215 is determined 609, the processor 405 reports 611 the interference 215 as an error. In one embodiment, the processor 405 mitigates 613 the error. For example, the processor 405 may direct a memory address 102 to a replacement memory cell 111, replacement memory address 102, and/or replacement data segment 106.

If no interference 215 is determined 609 or in response to reporting 611 the error and/or mitigating 613 the error, the processor 405 determines 615 if all memory cells 101, memory addresses 102, and/or data segments 106 have been tested and/or if the diagnostic is complete. If all memory cells 101, memory addresses 102, and/or data segments 106 have not been tested and/or if the diagnostic is not complete, the processor 405 may loop to select 601 a next given memory cell 101b. If the diagnostic is complete, the method 600 ends.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a processor;
a memory storing code executable by the processor to:
select a test mask based on a number of bits per memory cell in a memory, wherein the test mask stresses cell boundaries;
write the test mask to a plurality of memory cells; and
determine interference at a first memory cell.

2. The apparatus of claim 1, where the interference is determined from a value error.

3. The apparatus of claim 1, wherein the test mask is selected from the table:

| Bits per | |
|---|---|
| Memory Cell | Test Mask (Hex) |
| 1 | 0x5555555555555555 |
| 2 | 0xAAAAAAAAAAAAAAAA |
| 3 | 0x4924924924924924 |
| 3 | 0x2492492492492492 |
| 3 | 0x9249249249249249 |
| 4 | 0x8888888888888888 |
| 5 | 0x0842108421084210 |
| 5 | 0x1084210842108421 |
| 5 | 0x2108421084210842 |
| 5 | 0x4210842108421084 |
| 5 | 0x8421084210842108. |

4. The apparatus of claim 1, the processor further:
reporting the interference as an error; and
mitigating the interference.

5. The apparatus of claim 1, the processor further:
writing a mono pattern to neighbor memory cells;
writing a cell mask to a selected memory cell; and
determining neighbor interference at a first neighbor memory cell.

6. The apparatus of claim 5, wherein the mono pattern is zeros and the cell mask is ones.

7. The apparatus of claim 5, the processor further:
reporting the neighbor interference at the first neighbor memory cell as an error; and
mitigating the neighbor interference.

8. A method comprising:
selecting, by use of a processor, a test mask based on a number of bits per memory cell in a memory, wherein the test mask stresses cell boundaries;
writing the test mask to a plurality of memory cells; and
determining interference at a first memory cell.

9. The method of claim 8, where the interference is determined from a value error.

10. The method of claim 8, wherein the test mask is selected from the table:

| Bits per | |
|---|---|
| Memory Cell | Test Mask (Hex) |
| 1 | 0x5555555555555555 |
| 2 | 0xAAAAAAAAAAAAAAAA |
| 3 | 0x4924924924924924 |
| 3 | 0x2492492492492492 |
| 3 | 0x9249249249249249 |
| 4 | 0x8888888888888888 |
| 5 | 0x0842108421084210 |
| 5 | 0x1084210842108421 |
| 5 | 0x2108421084210842 |
| 5 | 0x4210842108421084 |
| 5 | 0x8421084210842108. |

11. The method of claim 8, the method further comprising:
reporting the interference as an error; and
mitigating the interference.

12. The method of claim 8, the method further comprising:
writing a mono pattern to neighbor memory cells;
writing a cell mask to a selected memory cell; and
determining neighbor interference at a first neighbor memory cell.

13. The method of claim 12, wherein the mono pattern is zeros and the cell mask is ones.

14. The method of claim 12, the method further comprising:
reporting the neighbor interference at the first neighbor memory cell as an error; and
mitigating the neighbor interference.

15. A program product comprising a computer readable storage medium that stores code executable by a processor, the executable code comprising code to:
select a test mask based on a number of bits per memory cell in a memory, wherein the test mask stresses cell boundaries;
write the test mask to a plurality of memory cells; and
determine interference at a first memory cell.

16. The program product of claim 15, where the interference is determined from a value error.

17. The program product of claim 15, wherein the test mask is selected from the table:

| Bits per | |
|---|---|
| Memory Cell | Test Mask (Hex) |
| 1 | 0x5555555555555555 |
| 2 | 0xAAAAAAAAAAAAAAAA |
| 3 | 0x4924924924924924 |
| 3 | 0x2492492492492492 |
| 3 | 0x9249249249249249 |
| 4 | 0x8888888888888888 |
| 5 | 0x0842108421084210 |
| 5 | 0x1084210842108421 |
| 5 | 0x2108421084210842 |
| 5 | 0x4210842108421084 |
| 5 | 0x8421084210842108. |

18. The program product of claim 15, the processor further:
reporting the interference as an error; and
mitigating the interference.

19. The program product of claim 15, the processor further:
writing a mono pattern to neighbor memory cells;
writing a cell mask to a selected memory cell; and
determining neighbor interference at a first neighbor memory cell.

20. The program product of claim 19, wherein the mono pattern is zeros and the cell mask is ones.
